(19) United States
(12) Patent Application Publication
(10) Pub. No.: US 2003/0098466 A1
(43) Pub. Date: May 29, 2003

(54) Capacitor element, method for manufacturing the same, semiconductor device and method for manufacturing the same

(75) Inventor: Yukio Morozumi, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/274,080

(22) Filed: Oct. 21, 2002

(30) Foreign Application Priority Data
Oct. 26, 2001 (JP) 2001-329134

(51) Int. Cl. H01L 31/0328

(52) U.S. Cl. 257/200

(57) ABSTRACT

The invention provides a capacitance element, its manufacturing method, a semiconductor device and its manufacturing method in which ferroelectric films can be readily processed, the generation of voids in dielectric films is restrained, and the coverage of films above the capacitance elements are enhanced. A method for manufacturing a capacitor element in accordance with the present invention includes: forming a bottom electrode on an element isolation film, forming a first interlayer dielectric film on the bottom electrode, forming trenches located on the bottom electrode in the first interlayer dielectric film, depositing a ferroelectric film in the trenches and on the first interlayer dielectric film, depositing a conductive film on the ferroelectric film and in the trenches, and embedding ferroelectric films and top electrodes in the trenches by polishing the conductive film, the ferroelectric film and the first interlayer dielectric film by a CMP method.

### BACKGROUND OF THE INVENTION

1. Field of Invention

The present invention relates to a capacitor element, a method for manufacturing the same, a semiconductor device and a method for manufacturing the same.

2. Description of Related Art

FIG. 6 is a cross-sectional view of a related art semiconductor device. The semiconductor device is a non-volatile memory using a ferroelectric capacitor (FeRAM; ferroelectric random-access memory).

First, a MOS transistor is formed on a silicon substrate 101.

More specifically, an element isolation film 102 is formed on a silicon substrate 101 by a LOCOS method, and a gate oxide film 103 is formed in an element region between the element isolation films by a thermal oxidation method. Then, a polysilicon film is deposited on the gate oxide film 103, and the polysilicon film is patterned to form a gate electrode 104 on the gate oxide film 103. Then, impurity ions are ion-injected in the silicon substrate 101 using the gate electrode as a mask. Then, sidewalls 105 are formed on side walls of the gate electrode 104, and impurity ions are ion-injected using the sidewalls and gate electrode as a mask, and a predetermined thermal treatment is conducted. As a result, low concentration diffusion layers are formed in LDD (Lightly Doped Drain) regions of the silicon substrate, and a source diffusion layer 107 and a drain diffusion layer 108 are formed in source/drain regions of the silicon substrate.

Then, a conductive film is deposited on the entire surface including the MOS transistor and the element isolation film, and the conductive film is patterned, such that a bottom electrode 110 is formed on the element isolation film 102. Then, a ferroelectric film is coated on the entire surface including the bottom electrode 110, and the ferroelectric film is patterned by ion milling or dry etching with chlorine family gas. As a result, ferroelectric film patterns 111a and 111b are formed on the bottom electrode 110. Then, a conductive film is deposited on the entire surface including the ferroelectric film patterns, and the conductive film is patterned by etching to thereby form top electrodes 112a and 112b on the ferroelectric film patterns. In this manner, capacitor elements are formed on the element isolation film.

Next, an interlayer dielectric film 113 is deposited on the entire surface including the capacitor elements and the MOS transistor. Then, a connection hole located above the drain diffusion layer 108, and connection holes located above the respective top electrodes 112a and 112b, are formed in the interlayer dielectric film 113. Then, an Al alloy film is deposited inside the connection holes and on the interlayer dielectric film 113, and the Al alloy film is patterned. As a result, an Al alloy wiring 114a connected to the drain diffusion layer 108 and the top electrode 112, and an Al alloy wiring 114b connected to the top electrode 112b, are formed on the interlayer dielectric film 113.

In the related art semiconductor device described above, the ferroelectric film is processed by ion milling or dry etching with chlorine family gas. However, in this process, polymer is generated, and the precision in processed configurations, the process stability, the yield and the selective ratio with respect to the ferroelectric film are poor, such that the processing is difficult, and the productivity is low.

Also, in the related art semiconductor device described above, film growth and patterning are repeated independently for each of the bottom electrodes, the ferroelectric films and the top electrodes. As a result, step differences may be formed due to matching deviations and side-etching (over etching of the ferroelectric film) among the bottom electrodes, the ferroelectric films and the top electrodes. This may cause a problem in that, after the interlayer dielectric film 113 is formed, voids 115 remain within the interlayer dielectric film and contaminants may be trapped in the voids. Also, the coverage of the Al alloy wirings 114a and 114b may lower due to the step differences, and this would hinder the miniaturization.

FIG. 7 is a cross-sectional view of another related art semiconductor device, where the same elements as those shown in FIG. 6 are indicated with the same reference numbers; only the different elements are described.

After forming the top electrodes 112a and 112b on the ferroelectric film pattern, a barrier film 109 is formed on the entire surface including the capacitor element and the MOS transistor. The barrier film 109 is a film required to shut off hydrogen or as an anti-reaction film, and is formed from a film of, for example, Al₂O₃, SiN or ZrO. In other words, when a hydrogen sintering process is conducted to improve the transistor characteristics, hydrogen may enter the interlayer dielectric film 113, but the film shields the capacitor element from the hydrogen. Next, an interlayer dielectric film 113 is deposited on the barrier film 109. The succeeding steps are the same as those for the aforementioned conventional semiconductor device.

In the above other related art semiconductor device, like the aforementioned related art semiconductor device, step differences may be formed due to matching deviations and side-etching among the bottom electrode 110, the ferroelectric films 111a and 111b and the top electrodes 112a and 112b. As a result, adhesion of the barrier film 109 becomes poor, such that the characteristics of the semiconductor device become unstable, and the reliability of the device become insufficient.

### SUMMARY OF THE INVENTION

In the aforementioned related art semiconductor device, there are problems in that the ferroelectric film is difficult to process, voids may be generated in the interlayer dielectric film, and the coverage of wirings over the capacitor element is poor. Also, in the other related art semiconductor device, there is a problem in that the adhesion of the barrier film is poor.

The present invention addresses the circumstances described above, and provides a capacitor element, its manufacturing method, a semiconductor device and its manufacturing method, in which ferroelectric films can be readily processed, the generation of voids in dielectric films is restrained, and the coverage of films over capacitor elements is enhanced.

To address or solve the problems described above, a capacitor element in accordance with the present invention includes:

a bottom electrode formed on a first dielectric film;

a second dielectric film formed on the bottom electrode;

a trench formed in the second dielectric film and located on the bottom electrode;

a ferroelectric film formed in the trench and disposed on the bottom electrode; and

a top electrode formed in the trench and disposed on the ferroelectric film.

Also, the capacitor element in accordance with the present invention may further include a barrier film formed between the ferroelectric film and the top electrode and inner side surfaces of the trench, respectively.

A capacitor element in accordance with another aspect of the present invention includes:

a bottom electrode formed on a first dielectric film;

a second dielectric film formed on the bottom electrode;

a trench formed in the second dielectric film and located on the bottom electrode;

a ferroelectric film embedded in the trench and disposed on the bottom electrode; and

a top electrode formed on the ferroelectric film.

Also, the capacitor element in accordance with the present invention may further include a barrier film formed between inner side surfaces of the trench and the ferroelectric film.

A method for manufacturing a capacitor element in accordance with the present invention includes:

forming a bottom electrode on a first dielectric film;

forming a second dielectric film on the bottom electrode;

forming a trench in the second dielectric film located on the bottom electrode;

forming a ferroelectric film in the trench and on the second dielectric film;

forming a top electrode material film on the ferroelectric film and in the trench; and

embedding a ferroelectric film and a top electrode material film in the trench by polishing the top electrode film material, the ferroelectric film and the second dielectric film by a CMP method.

According to the method for manufacturing a capacitor element, a trench is formed in a second dielectric film; a ferroelectric film and a top electrode material film are formed in the trench; the top electrode material film, the ferroelectric film and the second dielectric film are polished by a CMP method; and the top electrode and the ferroelectric film are simultaneously patterned. For this reason, matching deviations between the top electrode and the ferroelectric film can be avoided, and the generation of step differences due to side-etching (over-etching of the ferroelectric film) as in the related art technology can be restrained. As a result, the generation of voids in the interlayer dielectric films can be reduced or prevented, and the coverage of films on the capacitor elements can be enhanced.

A method for manufacturing a capacitor element in accordance with another aspect of the present invention includes:

forming a bottom electrode on a first dielectric film;

forming a second dielectric film on the bottom electrode;

forming a trench in the second dielectric film located on the bottom electrode;

forming a ferroelectric film in the trench and on the second dielectric film;

embedding a ferroelectric film in the trench by polishing the ferroelectric film by a CMP method; and

forming a top electrode on the ferroelectric film.

Also, the method for manufacturing a capacitor element in accordance with the present invention may further include, between forming the trench and forming the ferroelectric film, forming a barrier film on inner side surfaces of the trench.

According to the method for manufacturing a capacitor element, a trench is formed in a second dielectric film; barrier films are formed on inner surfaces of the trench; a ferroelectric film is deposited in the trench and on the second dielectric film; and the ferroelectric film is polished by a CMP method to thereby embed the ferroelectric film in the trench. For this reason, the generation of step differences due to side-etching (over-etching of the ferroelectric film) as in the related art technology can be restrained. As a result, the adhesion of the barrier films can be enhanced, the generation of voids in the interlayer dielectric films can be reduced or prevented, and the coverage of films on the capacitor elements can be enhanced.

Also, in the method for manufacturing a capacitor element in accordance with the present invention, forming the barrier film may include: depositing the barrier film in the trench and on the second dielectric film, and etching back the barrier film to thereby leave the barrier film on the inner side surfaces of the trench.

Also, in the method for manufacturing a capacitor element in accordance with the present invention, forming the ferroelectric film may include one of a solution coating method, a CVD method and a sputter method.

A semiconductor device in accordance with the present invention includes:

a transistor formed on a semiconductor substrate;

a first dielectric film formed on the semiconductor substrate;

a bottom electrode formed on the first dielectric film;

a second dielectric film formed on the bottom electrode;

a trench formed in the second dielectric film and located on the bottom electrode;

a ferroelectric film formed in the trench and disposed on the bottom electrode; and

a top electrode formed in the trench and disposed on the ferroelectric film,

a capacitance element formed of the top electrode, the ferroelectric film and the bottom electrode being electrically connected to the transistor.

The semiconductor device in accordance with the present invention may further include a barrier film formed between the ferroelectric film and the top electrode and inner side surfaces of the trench, respectively.

A semiconductor device in accordance with another aspect of the present invention includes:

a transistor formed on a semiconductor substrate;

a first dielectric film formed on the semiconductor substrate;

a bottom electrode formed on the first dielectric film;

a second dielectric film formed on the bottom electrode;

a trench formed in the second dielectric film and located on the bottom electrode;

a ferroelectric film embedded in the trench and disposed on the bottom electrode; and

a top electrode formed on the ferroelectric film,

a capacitance element formed of the top electrode, the ferroelectric film and the bottom electrode being electrically connected to the transistor.

Also, the semiconductor device in accordance with the present invention may further include barrier films formed between inner side surfaces of the trench and the ferroelectric film.

A method for manufacturing a semiconductor device in accordance with the present invention includes:

forming a transistor on a semiconductor substrate;

forming a first dielectric film on the semiconductor substrate;

forming an bottom electrode on the first dielectric film;

forming a second dielectric film on the bottom electrode;

forming a trench in the second dielectric film located on the bottom electrode;

forming a ferroelectric film in the trench and on the bottom electrode; forming a top electrode material film on the ferroelectric film and in the trench;

embedding the ferroelectric film and the top electrode material film in the trench by polishing the top electrode film material, the ferroelectric film and the second dielectric film by a CMP method, to thereby form a ferroelectric film and a top electrode in the trench; and

forming a wiring for electrically connecting a capacitor element formed of the top electrode, the ferroelectric film and the bottom electrode to the transistor.

A method for manufacturing a semiconductor device in accordance with another aspect of the present invention includes:

forming a transistor on a semiconductor substrate;

forming a first dielectric film on the semiconductor substrate;

forming an bottom electrode on the first dielectric film;

forming a second dielectric film on the bottom electrode;

forming a trench in the second dielectric film located on the bottom electrode;

forming a ferroelectric film in the trench and on the second dielectric;

embedding the ferroelectric film in the trench by polishing the ferroelectric film by a CMP method;

forming a top electrode on the ferroelectric film; and

forming a wiring for electrically connecting a capacitor element formed of the top electrode, the ferroelectric film and the bottom electrode to the transistor.

Also, the method for manufacturing a semiconductor device in accordance with the present invention may further include, between forming the trench and forming the ferroelectric film, forming a barrier film on inner side surfaces of the trench.

Also, in the method for manufacturing a semiconductor device in accordance with the present invention, forming the barrier film may include: depositing the barrier film in the trench and on the second dielectric film, and etching back the barrier film to thereby leave the barrier film on the inner side surfaces of the trench.

Also, in the method for manufacturing a semiconductor device in accordance with the present invention, forming the ferroelectric film may include one of a solution coating method, a CVD method and a sputter method.

### BRIEF DESCRIPTION OF THE DRAWINGS

FIGS. 1(a)-(d) are cross-sectional views showing a method for manufacturing a semiconductor device in accordance with a first embodiment of the present invention;

FIGS. 2(a)-(d) are cross-sectional views showing a method for manufacturing a semiconductor device in accordance with a second embodiment of the present invention;

FIGS. 3(a)-(d) are cross-sectional views showing a method for manufacturing a semiconductor device in accordance with a third embodiment of the present invention;

FIGS. 4(a)-(d) are cross-sectional views showing a method for manufacturing a semiconductor device in accordance with a fourth embodiment of the present invention;

FIGS. 5(a)-(d) are cross-sectional views showing a method for manufacturing a semiconductor device in accordance with a fifth embodiment of the present invention;

FIG. 6 is a cross-sectional view showing a related art semiconductor device;

FIG. 7 is a cross-sectional view showing another related art semiconductor device.

### DETAILED DESCRIPTION OF PREFERRED EMBODIMENTS

Embodiments of the present invention will be described below with reference to the accompanying drawings.

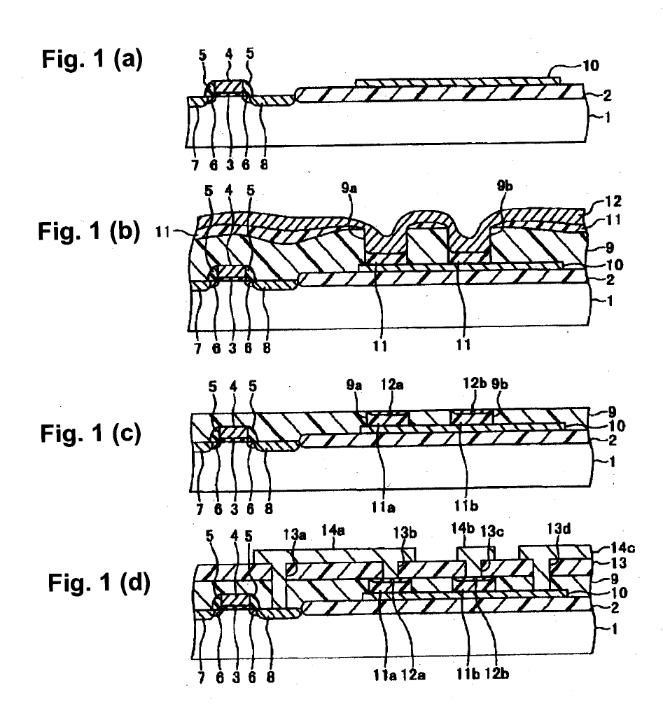

FIGS. 1(a)-(d) are cross-sectional views showing a method for manufacturing a semiconductor device in accordance with a first embodiment of the present invention. The semiconductor device is a non-volatile memory using a ferroelectric capacitor (FeRAM; ferroelectric random-access memory).

First, as show in FIGS. 1(a)-1(d), a MOS transistor is formed on a silicon substrate 1.

More specifically, element isolation films 2 are formed on a silicon substrate 1 by a LOCOS method, and a gate oxide film 3 is formed in an element region between the element isolation films 2 by a thermal oxidation method. Then, a polysilicon film is deposited on the gate oxide film 3 by a CVD (Chemical Vapor Deposition) method, and the polysilicon film is patterned to form a gate electrode 4 on the gate oxide film 3. Then, impurity ions are ion-injected in the silicon substrate 1 using the gate electrode 4 as a mask. Then, sidewalls 5 are formed on side walls of the gate electrode 4, and impurity ions are ion-injected using the sidewalls 5 and gate electrode 4 as a mask, and a predetermined thermal treatment is conducted. As a result, low concentration diffusion layers 6 are formed in LDD (Lightly Doped Drain) regions of the silicon substrate 1, and a source diffusion layer 7 and a drain diffusion layer 8 are formed in source/drain regions of the silicon substrate 1.

Then, a conductive film, such as a platinum (Pt) film having a thickness of about 100-300 nm, is deposited on the entire surface including the MOS transistor and the element isolation film 2 by, for example, a sputter method, and the conductive film is patterned. As a result, a bottom electrode 10 is formed on the element isolation film 2.

Thereafter, as shown in FIG. 1(b), a first interlayer dielectric film 9, such as a silicon oxide film having a thickness of about 500-1000 nm, is deposited on the entire surface including the bottom electrode 10 is deposited by a CVD method. Then, a photoresist film (not shown) is coated on the first interlayer dielectric film 9, and the photoresist film is exposed and developed to form a resist pattern on the first interlayer dielectric film 9. Then, the interlayer dielectric film 9 is etched by using the resist pattern as a mask, such that trenches 9a and 9b are formed in the first interlayer dielectric film 9 located on the bottom electrode.

Next, a ferroelectric film 11 formed of PZT (lead zirconate titanate with a perovskite structure; Pb (Zr, Ti) O₃), SBT (SrBi₂ (Ta, Nb)₂ O₉), BST ((Ba, Sr) TiO₃) is formed in the trench and on the first interlayer dielectric film by a solution coating method (Chemical Solution Deposition), a CVD method or a sputter method. The ferroelectric film 11 may have a thickness at its plane section of about 100-300 nm.

The solution coating method is generally classified into a sol-gel method and a MOD method. Generally, the sol-gel method uses as a coating raw material a sol solution having a M-O-M bond, which is created by subjecting metal alkoxides dissolved in solvent with a calculated fixed quantity of water being added thereto to hydrolysis and polycondensation. The MOD method uses as a coating raw material a solution in which metal salts of carboxylic acids having an O-M bond is dissolved in organic solution.

As the coating raw material, any of the known or later developed metal oxides ferroelectric may be used. For example, barium titanate (BaTiO₃), lead zirconate (PbTiO₃), PLZT in which La is added in solid solution of PbZrO₃ and PbTiO₃ may be suggested as typical examples thereof. In addition, LiNBO₃ and LiTaO₃ may also be suggested as typical examples thereof. Also, the ferroelectric precursor gel is a mixture of required metals and organic compounds, and any of the known or later developed compounds can be used. For example, as a precursor of SBT, the one described in Japanese Laid-open Patent Application HEI 11-80181 may be used. In this case, an alkoxide of Sr (for example, Sr (OC₂H₄OCH₃)₂) is reacted in alcohol (for example, methoxyethanol) with an alkoxide of Bi (for example, Bi(OC₂H₅)₂) to generate a double alkoxide of Sr—Bi (for example, Sr[Bi(OR)₄]₂), which is then reacted with an alkoxide of Ta (for example, Ta(OC₂H₅)₅), to thereby obtain a solution of a complex alkoxide of Sr—Bi—Ta that is used as the precursor.

The aforementioned CVD method uses as a raw material a gasified form of metal salt having an O-M bond, metal complex, or alkoxide of metal, which is thermally decomposed on the substrate surface that is heated in a vacuum container while being reacted with oxygen and deposited on the substrate surface.

The aforementioned sputter method is conducted as follows. Argon ions and oxygen ions, which are generated by glow discharge in an argon-oxygen atmosphere under reduced pressures, are bombarded against plural kinds of metals or alloys, plural kinds of powders or sintered compacts of oxides, or sintered compacts of oxides having compositions close to the compositions of a thin film, and their momentum is used to sputter out the raw materials to deposit thin film raw materials from the gas phase, which may be subjected to an oxidation-reaction with the oxygen in the atmosphere or whose shortage of oxygen may be supplemented, to obtain an oxide. There are: a type in which the oxide during its deposition under high substrate temperatures is crystallized, and a type in which the oxide is deposited under low substrate temperatures and then heated to high temperatures for its crystallization.

Then, a conductive film 12 formed of a platinum film or a deposited layered film of a platinum film and a tungsten (W) film, having a thickness of about 100-300 nm, is deposited on the ferroelectric film 11 and in the trenches 9a and 9b by, for example, a sputter method.

Then, as shown in FIG. 1(c), the conductive film 12, the ferroelectric film 11 and the first interlayer dielectric film 9 are polished by a CMP (Chemical Mechanical Polishing) method. As a result, the first interlayer dielectric film 9 is planarized, and the top electrodes 12a and 12b and the ferroelectric films 11a and 11b are simultaneously patterned. In other words, the ferroelectric film 11 and the conductive films 12 that exist on the first interlayer dielectric film are polished and removed, the ferroelectric film 11a and the top electrode 12a thereon are embedded in the trench 9a, and the ferroelectric film 11b and the top electrode 12b thereon are embedded in the trench 9b. In this manner, on the element isolation film 2 is formed a capacitor element composed of the top electrode 12a, the ferroelectric film 11a and the bottom electrode 10 and a capacitor element composed of the top electrode 12b, the ferroelectric film 11b and the bottom electrode 10.

The bottom electrode 10 is described as being formed on the element isolation film 2. However, a film formed of a high melting point metal, such as Ti, Ta, Ir or W, or its nitride film or its oxide film, may be formed on the element isolation film 2, and the bottom electrode may be formed on such a film. Also, the top electrodes 12a and 12b are formed on the ferroelectric films 11a and 11b are formed. However, a film formed of a high melting point metal, such as Ti, Ta, Ir or W, or its nitride film or its oxide film, may be formed on the ferroelectric films, and the top electrodes may be formed on such a film. Each of the high melting point metal film, its nitride film or its oxide film enhances the bonding property of the bottom electrode with respect to its lower layer, or the bonding property of the top electrodes with respect to its lower layers, and plays a role of oxygen traps.

Next, as shown in FIG. 1(d), a second interlayer dielectric film 13, such as a silicon oxide film, is deposited on the entire surface including the capacitor elements and the MOS transistor by a CVD method. Then, a photoresist film (not shown) is coated on the second interlayer dielectric film 13, and the photoresist film is exposed and developed, such that a photoresist pattern is formed on the second interlayer dielectric film 13. Next, the first and second interlayer dielectric films 9 and 13 are etched using the resist pattern as a mask. As a result, a connection hole 13a located above the drain diffusion layer 8, connection holes 13b and 13c located above the respective top electrodes 12a and 12b, and a connection hole 13d located above the bottom electrode 10 are formed in the first and second interlayer dielectric films.

Next, an Al alloy film is deposited by a sputter method in the connection holes and on the second interlayer dielectric film 13. Then, a photoresist film (not shown) is coated on the Al alloy film, and the photoresist film is exposed and developed, to thereby form a resist pattern on the Al alloy film. Next, the Al alloy film is etched by using the resist pattern as a mask. As a result, on the second interlayer dielectric film 13 is formed an Al alloy wiring 14a connected to the drain diffusion layer 8 and the top electrode 12a, an Al alloy wiring 14b connected to the top electrode 12b, and an Al alloy wiring 14c connected to the bottom electrode 10.

The semiconductor device thus manufactured has a structure shown in FIG. 1(d). More specifically, the element isolation films 2 are formed on the surface of the silicon substrate 1, and the MOS transistor is formed in an element region between the element isolation films. The bottom electrode 10 is formed on the element isolation film 2, and the first interlayer dielectric film 9 formed on the bottom electrode 10, the element isolation film 2 and the MOS transistor. The trenches 9a and 9b located on the bottom electrode 10 are formed in the first interlayer dielectric film 9. The ferroelectric films 11a and 11b and the top electrodes 12a and 12b are embedded in the trenches 9a and 9b. The top electrodes 12a and 12b, the corresponding ferroelectric films 11a and 11b, and the bottom electrode 10 compose capacitance elements. The top electrode 12a is electrically connected to the drain diffusion layer 8 of the MOS transistor through the Al alloy wiring 14a. The top electrode 12b is electrically connected to the Al alloy wiring 14b, and the bottom electrode 10 is electrically connected to the Al alloy wiring 14c.

In accordance with the first embodiment described above, the trenches 9a and 9b are formed in the first interlayer dielectric film 9, the ferroelectric film 11 and the conductive film 12 are formed in the trenches, the conductive film 12, the ferroelectric film 11 and the first interlayer dielectric film 9 are polished by a CMP method, and the top electrodes and the ferroelectric films are simultaneously patterned. For this reason, matching deviations between the top electrodes 12a and 12b and the ferroelectric films 11a and 11b can be avoided, such that the generation of step differences by side etching (over-etching of the ferroelectric films) can be restrained. By this, the generation of voids in the interlayer dielectric film can be avoided, and the coverage of Al alloy wirings can be enhanced. Accordingly, the yield is enhanced, the reliability of the device is enhanced, and further miniaturizations can be accommodated.

Furthermore, in accordance with the first embodiment, the ferroelectric films and the top electrodes are processed by a CMP method, and not by a dry etching method. As a result, polymers are not generated; the measurement accuracy, the precision in processed configurations, the processing stability, and the yield can be enhanced; and they can be readily processed and excellent in mass production.

In the first embodiment described above, the connection holes 13a-13d are formed through etching the first and second interlayer dielectric films 9 and 13. Since the drain diffusion layer 8 of the MOS transistor, the top electrodes 12a and 12b of the capacitance elements, and the bottom electrode 10 are located at different depths, the connection hole 13a on the drain diffusion layer 8 and the connection holes 13b-13d on the top electrodes and the bottom electrode can also be formed by independent etching processes. More specifically, after an etching process is performed for forming the connection hole 13a, etching processes for forming the connection holes 13b-13d can be performed. The connection holes 13a-13d may be formed into tapered configurations by etching for the purpose of enhancing the adhesion of the Al alloy wirings 14a-14c, and embedded plugs, such as tungsten plugs, may be disposed inside the connection holes to achieve secure connection of relevant parts to the Al alloy wirings.

Also, in the first embodiment described above, the bottom electrode 10 of the capacitance elements is formed on the element isolation film 2. However, a dielectric film may be formed on the element isolation film 2, and the bottom electrode of the capacitance elements may be formed on the dielectric film.

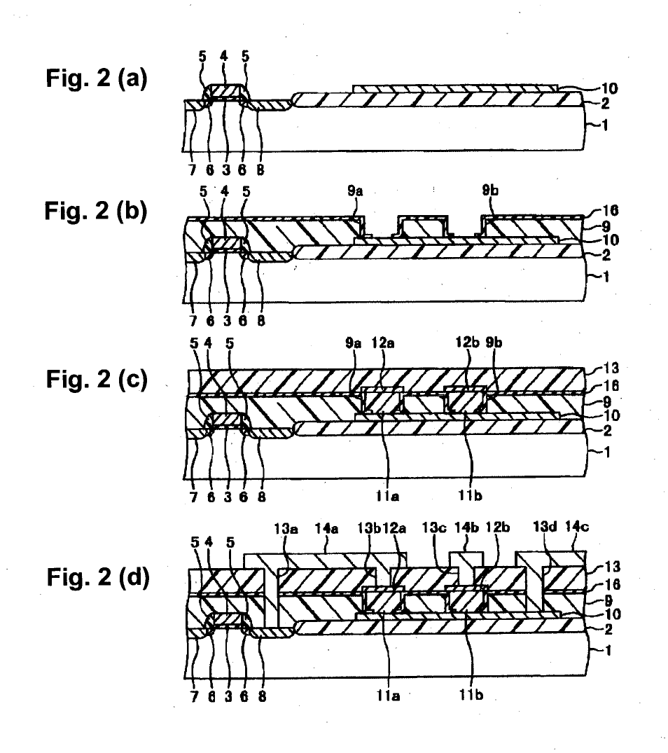

FIGS. 2(a)-(d) are cross-sectional views showing a method for manufacturing a semiconductor device in accordance with a second embodiment of the present invention. The same parts as those shown in FIGS. 1(a)-(d) are indicated by the same reference numbers, and only different parts will be described.

As shown in FIG. 2(b), trenches 9a and 9b located on the bottom electrode 10 are formed in the first interlayer dielectric film 9. Then, a barrier film 16 is formed on surfaces within the trenches and on the first interlayer dielectric film by a sputter method or a CVD method. The barrier film 16 is a film required to shut off hydrogen or as an anti-reaction film, and is formed from a film of, for example, Al₂O₃, SiN or ZrO. In other words, when a hydrogen sintering process is conducted to enhance the transistor characteristics, hydrogen may enter the interlayer dielectric film 9, but the film shields off the capacitor elements from the hydrogen. Next, the barrier film 16 at bottom sections of the trenches is opened by a photolithography technique and an etching technique to thereby expose the bottom electrode 10 at the bottom sections of the trenches.

Next, as shown in FIG. 2(c), a ferroelectric film of PZT, SBT or BST is formed in the trenches and on the barrier film 16 by a solution coating method, a CVD method or a sputter method. Then, the ferroelectric film is polished by a CMP method, whereby ferroelectric films 11a and 11b are embedded in the trenches.

Next, a conductive film is deposited on the entire surface including the ferroelectric films 11a and 11b by a sputter method. Then, a photoresist film (not shown) is coated on the conductive film, and the photoresist film is exposed and developed to thereby form a resist pattern on the conductive film. By etching the conductive film using the resist pattern as a mask, top electrodes 12a and 12b are formed on the ferroelectric films 11a and 11b, respectively. Then, a second interlayer dielectric film 13, such as a silicon oxide film, is deposited on the entire surface including the top electrodes by a CVD method. The succeeding steps are the same as those of the first embodiment.

The semiconductor device thus manufactured has a structure shown in FIG. 2(d). More specifically, the trenches 9a and 9b located on the bottom electrode 10 are formed in the first interlayer dielectric film 9. The barrier films 16 are formed on inner side walls of the trenches 9a and 9b, and the ferroelectric films 11a and 11b are embedded in the trenches 9a and 9b. The top electrodes 12a and 12b are formed on the corresponding ferroelectric films 11a and 11b.

In accordance with the second embodiment described above, the trenches 9a and 9b are formed in the first interlayer dielectric film 9, the barrier film 16 is formed on the inner surfaces of the trenches and on the interlayer dielectric film 9, the ferroelectric film is deposited on the barrier layer 16 and in the trenches, and the ferroelectric film is polished by a CMP method to embed the ferroelectric films 11a and 11b in the trenches. For this reason, the generation of step differences due to side etching (over-etching of the ferroelectric films) like in the related art technology can be restrained. By this, the adhesion of the barrier films 16 can be enhanced, the generation of voids in the interlayer dielectric film can be reduced or avoided, and the coverage of Al alloy wirings can be enhanced. Accordingly, the yield is enhanced, or the reliability of the device is enhanced, and further miniaturizations can be accommodated.

Furthermore, in accordance with the second embodiment, the ferroelectric films and the top electrodes are processed by a CMP method, and not by a dry etching method. As a result, polymers are not generated; the measurement accuracy, the precision in processed configurations, the processing stability, and the yield can be enhanced; and they can be readily processed and excellent in mass production.

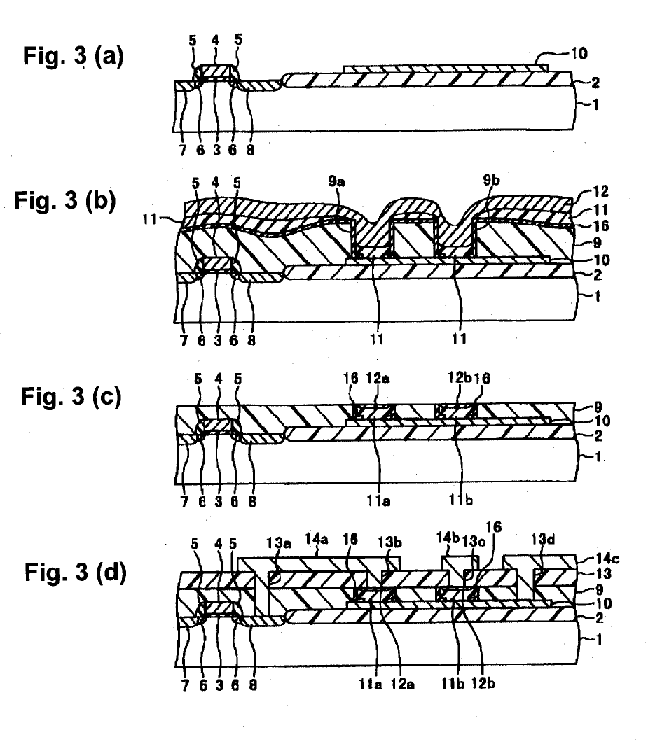

FIGS. 3(a)-(d) are cross-sectional views showing a method for manufacturing a semiconductor device in accordance with a third embodiment of the present invention. The same parts as those shown in FIGS. 1(a)-(d) are indicated by the same reference numbers, and only different parts will be described.

As shown in FIG. 3(b), trenches 9a and 9b are formed in the first interlayer dielectric film 9. Then, a barrier film 16 is formed on surfaces in the trenches and on the first interlayer dielectric film by, for example, a sputter method or a CVD method. This barrier film 16 is the same as the barrier film in the second embodiment. Next, a ferroelectric film 11 of PZT, SBT or BST is formed in the trenches and on the barrier film 16 by a solution coating method, a CVD method or a sputter method. Then, a conductive film 12 is deposited on the ferroelectric film 11 and in the trenches 9a and 9b.

Then, as shown in FIG. 3(c), the conductive film 12, the ferroelectric film 11, the barrier film 16 and the first interlayer dielectric film 9 are polished by a CMP method. As a result, the first interlayer dielectric film 9 is planarized, and the top electrodes 12a and 12b and the ferroelectric films 11a and 11b are simultaneously patterned. The succeeding steps are the same as those of the first embodiment.

The semiconductor device thus manufactured has a structure shown in FIG. 3(d). More specifically, the trenches 9a and 9b located on the bottom electrode 10 are formed in the first interlayer dielectric film 9. The barrier films 16 are formed on the inner side surfaces of the trenches 9a and 9b, and the ferroelectric films 11a and 11b and the top electrodes 12a and 12b are embedded in the trenches 9a and 9b.

By the third embodiment described above, the same effects as those obtained by the first embodiment can be obtained. Moreover, the barrier films 16 are formed on the inner side surfaces of the trenches, such that the adhesion of the barrier layers 16 can be enhanced.

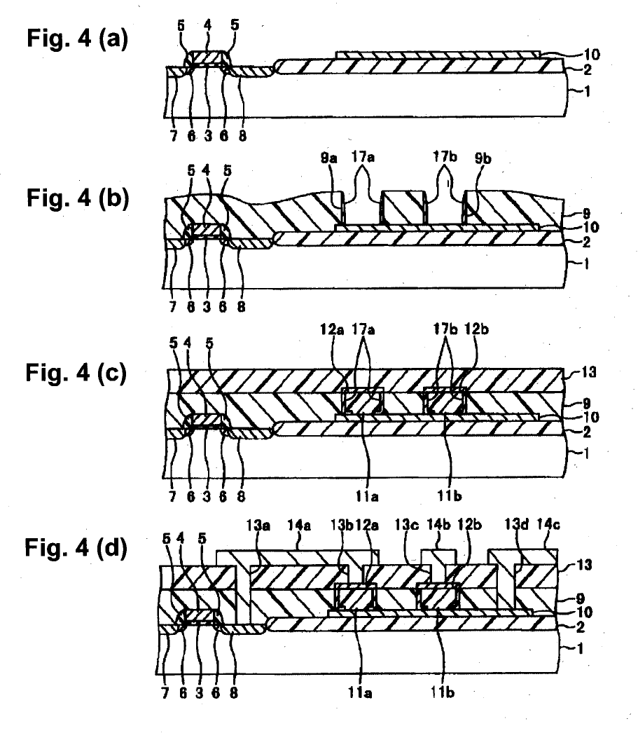

FIGS. 4(a)-(d) are cross-sectional views showing a method for manufacturing a semiconductor device in accordance with a fourth embodiment of the present invention. The same parts as those shown in FIGS. 2(a)-2(d) are indicated by the same reference numbers, and only different parts will be described.

As shown in FIG. 4(b), trenches 9a and 9b located on the bottom electrode 10 are formed in the first interlayer dielectric film 9. Then, a barrier film is deposited in the trenches and on the first interlayer dielectric film by, for example, a sputter method or a CVD method. Then, this barrier film is etched back, to thereby leave barrier films 17a and 17b on the inner side surfaces of the trenches.

Next, as shown in FIG. 4(c), a ferroelectric film of PZT, SBT or BST is formed in the trenches and on the first interlayer dielectric film 9 by a solution coating method, a CVD method or a sputter method. Then, by polishing the ferroelectric film by a CMP method, ferroelectric films 11a and 11b are embedded in the trenches. The succeeding steps are the same as those of the second embodiment.

The fourth embodiment also provides the same effects as those of the second embodiment.

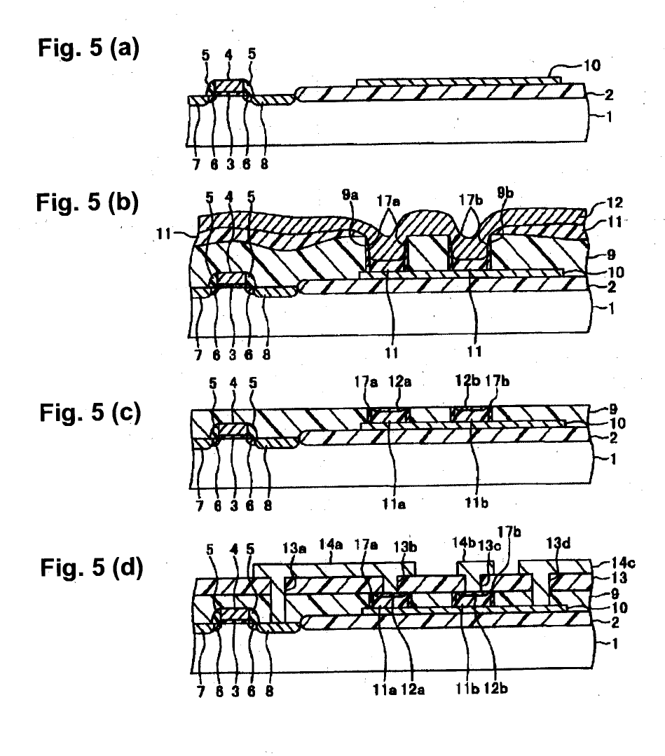

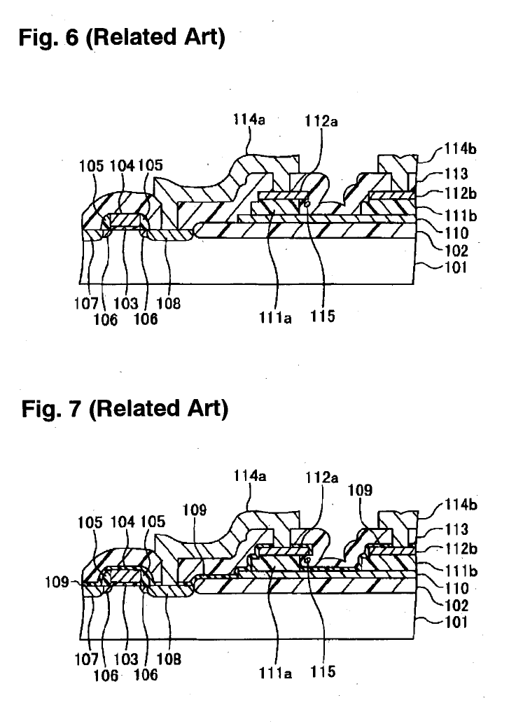

FIGS. 5(a)-(d) are cross-sectional views showing a method for manufacturing a semiconductor device in accordance with a fifth embodiment of the present invention. The same parts as those shown in FIGS. 3(a)-3(d) are indicated by the same reference numbers, and only different parts will be described.

As shown in FIG. 5(b), trenches 9a and 9b located on the bottom electrode 10 are formed in the first interlayer dielectric film 9. Then, a barrier film is deposited on surfaces within the trenches and on the first interlayer dielectric film by, for example, a sputter method or a CVD method. Then, this barrier film is etched back to leave barrier films 17a and 17b on inner side surfaces of the trenches. Next, a ferroelectric film 11 of PZT, SBT or BST is formed in the trenches and on the first interlayer dielectric film 9 by a solution coating method, a CVD method or a sputter method. Then, a conductive film 12 is deposited on the ferroelectric film 11 and in the trenches 9a and 9b. The succeeding steps are the same as those of the third embodiment.

The fifth embodiment also provides the same effects as those of the third embodiment.

It is noted that the present invention is not limited to the embodiments described above, and many modifications can be made and implemented.

[Effects of the Invention]

As described above, in accordance with the present invention, trenches are formed in a second dielectric film, a ferroelectric film and a top electrode material film are formed in the trenches, the top electrode material film, the ferroelectric film and the second dielectric film are polished by a CMP method, such that top electrodes and ferroelectric films are simultaneously patterned. Accordingly, the present invention provides a capacitance element, its manufacturing method, a semiconductor device and its manufacturing method in which ferroelectric films can be readily processed, the generation of voids in dielectric films is restrained, and the coverage of films above the capacitance elements are enhanced.

What is claimed is:

1. A capacitor element, comprising:
a first dielectric film;
a bottom electrode formed on the first dielectric film;
a second dielectric film formed on the bottom electrode;
a trench formed in the second dielectric film and located on the bottom electrode;
a ferroelectric film formed in the trench and disposed on the bottom electrode; and
a top electrode formed in the trench and disposed on the ferroelectric film.

2. The capacitor element according to claim 1, further comprising a barrier film formed between the ferroelectric film and the top electrode and inner side surfaces of the trench, respectively.

3. A capacitor element, comprising:
a first dielectric film;
a bottom electrode formed on the first dielectric film;
a second dielectric film formed on the bottom electrode;
a trench formed in the second dielectric film and located on the bottom electrode;
a ferroelectric film embedded in the trench and disposed on the bottom electrode; and
a top electrode formed on the ferroelectric film.

4. The capacitor element according to claim 3, further comprising barrier films formed between inner side surfaces of the trench and the ferroelectric film.

5. A method for manufacturing a capacitor element, comprising:
forming a bottom electrode on a first dielectric film;
forming a second dielectric film on the bottom electrode;
forming a trench in the second dielectric film located on the bottom electrode;
forming a ferroelectric film in the trench and on the second dielectric film;
forming a top electrode material film on the ferroelectric film and in the trench; and
embedding a ferroelectric film and a top electrode material film in the trench by polishing the top electrode film material, the ferroelectric film and the second dielectric film by a CMP method.

6. A method for manufacturing a capacitor element, the method comprising:
forming a bottom electrode on a first dielectric film;
forming a second dielectric film on the bottom electrode;
forming a trench in the second dielectric film located on the bottom electrode;
forming a ferroelectric film in the trench and on the second dielectric film;
embedding a ferroelectric film in the trench by polishing the ferroelectric film by a CMP method; and
forming a top electrode on the ferroelectric film.

7. The method for manufacturing a capacitor element according to claim 6, further comprising, between forming the trench and forming the ferroelectric film, forming a barrier film on inner side surfaces of the trench.

8. The method for manufacturing a capacitor element according to claim 7, the step of forming the barrier film including: depositing the barrier film in the trench and on the second dielectric film, and etching back the barrier film to thereby leave the barrier film on the inner side surfaces of the trench.

9. The method for manufacturing a capacitor element according to claim 5, forming the ferroelectric film including one of a solution coating method, a CVD method and a sputter method.

10. A semiconductor device, comprising:
a semiconductor substrate;
a transistor formed on the semiconductor substrate;
a first dielectric film formed on the semiconductor substrate;
a bottom electrode formed on the first dielectric film;
a second dielectric film formed on the bottom electrode;
a trench formed in the second dielectric film and located on the bottom electrode;
a ferroelectric film formed in the trench and disposed on the bottom electrode; and
a top electrode formed in the trench and disposed on the ferroelectric film,
the top electrode, the ferroelectric film and the bottom electrode forming a capacitance element that is electrically connected to the transistor.

11. The semiconductor device according to claim 10, further comprising a barrier film formed between the ferroelectric film and the top electrode and inner side surfaces of the trench, respectively.

12. The semiconductor device, comprising:
a semiconductor substrate;
a transistor formed on the semiconductor substrate;
a first dielectric film formed on the semiconductor substrate;
a bottom electrode formed on the first dielectric film;
a second dielectric film formed on the bottom electrode;
a trench formed in the second dielectric film and located on the bottom electrode;
a ferroelectric film embedded in the trench and disposed on the bottom electrode; and
a top electrode formed on the ferroelectric film, the top electrode, the ferroelectric film and the bottom electrode forming a capacitance element that is electrically connected to the transistor.

13. The semiconductor device according to claim 12, further comprising barrier films formed between inner side surfaces of the trench and the ferroelectric film.

14. A method for manufacturing a semiconductor device, comprising:
forming a transistor on a semiconductor substrate;
forming a first dielectric film on the semiconductor substrate;
forming an bottom electrode on the first dielectric film;
forming a second dielectric film on the bottom electrode;
forming a trench in the second dielectric film located on the bottom electrode;
forming a ferroelectric film in the trench and on the bottom electrode;
forming a top electrode material film on the ferroelectric film and in the trench;
embedding the ferroelectric film and the top electrode material film in the trench by polishing the top electrode film material, the ferroelectric film and the second dielectric film by a CMP method, to thereby form a ferroelectric film and a top electrode in the trench; and
forming a wiring for electrically connecting a capacitor element formed of the top electrode, the ferroelectric film and the bottom electrode to the transistor.

15. A method for manufacturing a semiconductor device, comprising:
forming a transistor on a semiconductor substrate;
forming a first dielectric film on the semiconductor substrate;
forming a bottom electrode on the first dielectric film;
forming a second dielectric film on the bottom electrode;
forming a trench in the second dielectric film located on the bottom electrode;
forming a ferroelectric film in the trench and on the second dielectric;
embedding the ferroelectric film in the trench by polishing the ferroelectric film by a CMP method;
forming a top electrode on the ferroelectric film; and
forming a wiring for electrically connecting a capacitor element formed of the top electrode, the ferroelectric film and the bottom electrode to the transistor.

16. The method for manufacturing a semiconductor device according to claim 14, further comprising, between forming the trench and forming the ferroelectric film, forming a barrier film on inner side surfaces of the trench.

17. The method for manufacturing a semiconductor device according to claim 16, the step of forming the barrier film including depositing the barrier film in the trench and on the second dielectric film, and etching back the barrier film to thereby leave the barrier film on the inner side surfaces of the trench.

18. The method for manufacturing a semiconductor device according to claim 14, forming the ferroelectric film including one of a solution coating method, a CVD method and a sputter method.
